(19) United States
(12) Patent Application Publication
(10) Pub. No.: US 2014/0333186 A1
(43) Pub. Date: Nov. 13, 2014

(54) MOUNTING APPARATUS

(71) Applicant: HON HAI PRECISION INDUSTRY CO., LTD., New Taipei (TW)

(72) Inventor: CHEN-LU FAN, New Taipei (TW)

(73) Assignee: HON HAI PRECISION INDUSTRY CO., LTD., New Taipei (TW)

(21) Appl. No.: 14/100,188

(22) Filed: Dec. 9, 2013

(30) Foreign Application Priority Data
May 7, 2013 (TW) 102116227

(51) Int. Cl. H05K 5/02

(52) U.S. Cl. CPC H05K 5/0217
USPC 312/223.1

(57) ABSTRACT

A mounting apparatus includes a panel cage, a first securing member securing a first LCD, a second securing member securing a second LCD, and a cover secured to the panel cage. One of the first securing member and the second securing member is alternatively secured to the panel cage. When the first securing member is secured to the panel cage, the first LCD is located between the first securing member and the cover. When the second securing member is secured to the panel cage, the second LCD is located between the panel cage and the second securing member.

### BACKGROUND

1. Technical Field

The present disclosure relates to mounting apparatuses, and particularly to a mounting apparatus for securing different liquid crystal displays (LCD).

2. Description of Related Art

LCDS are used in many kinds of electronic devices, such as personal computers, servers, or notebooks. The LCDS have different sizes, it needs for different panel cages for securing different LCDS, that is expensive and inconvenient. Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a mounting apparatus and a first LCD in accordance with an embodiment.

FIG. 2 similar to FIG. 2, but viewed from a different aspect.

FIG. 3 is an exploded, isometric view of the mounting apparatus of FIG. 1, and a first securing member and the first LCD are secured to the panel cage.

FIG. 4 is an assembled view of the mounting apparatus of FIG. 1.

FIG. 5 is an exploded, isometric view of the mounting apparatus and a second LCD in accordance with another embodiment.

FIG. 6 is an assembled view of the mounting apparatus of FIG. 5.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

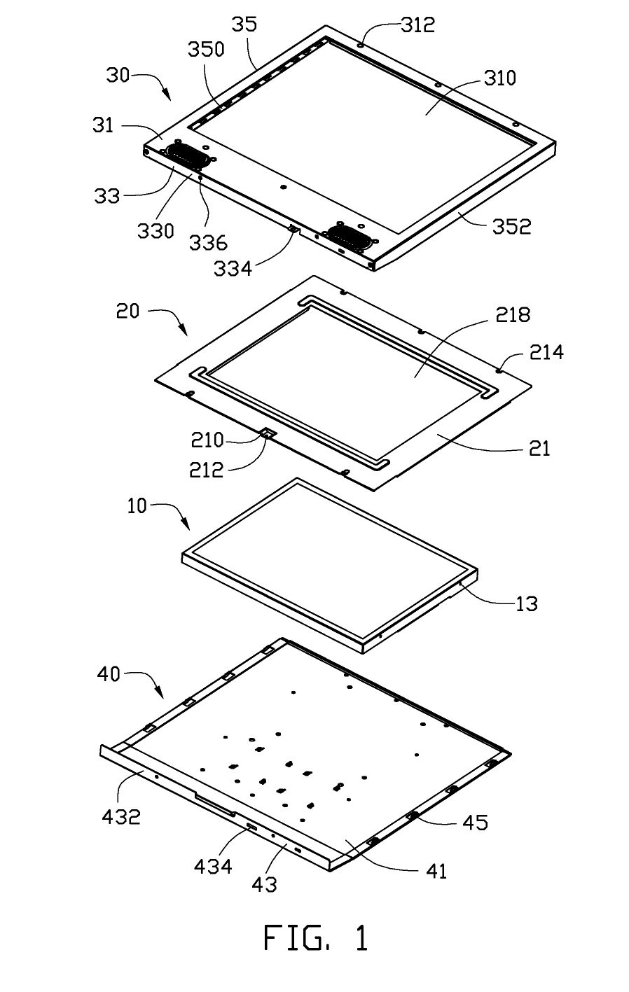

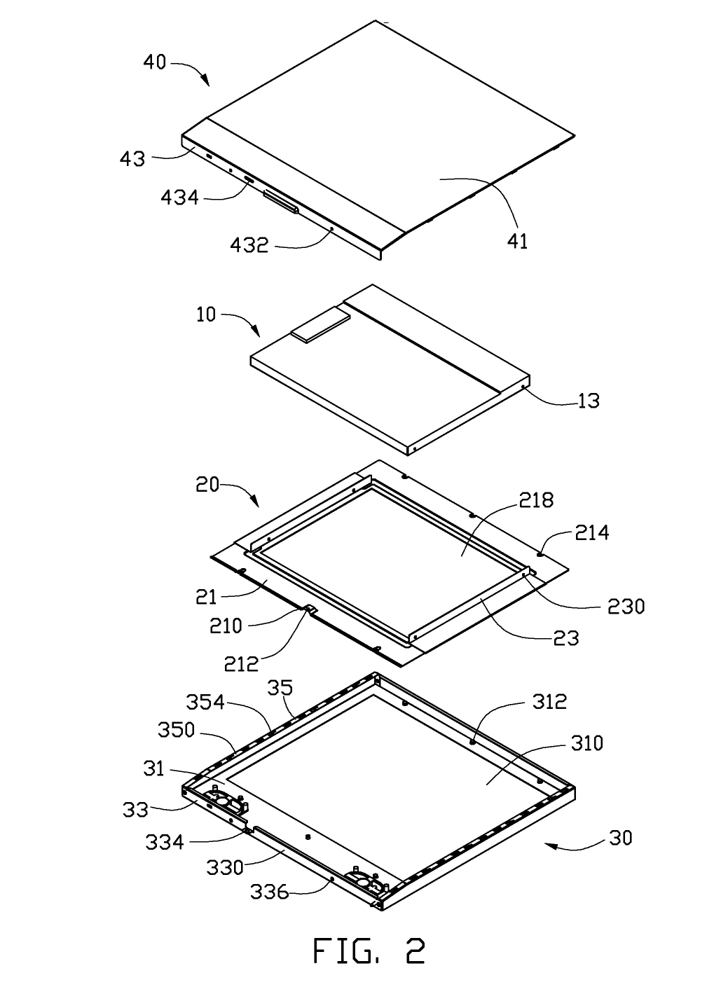

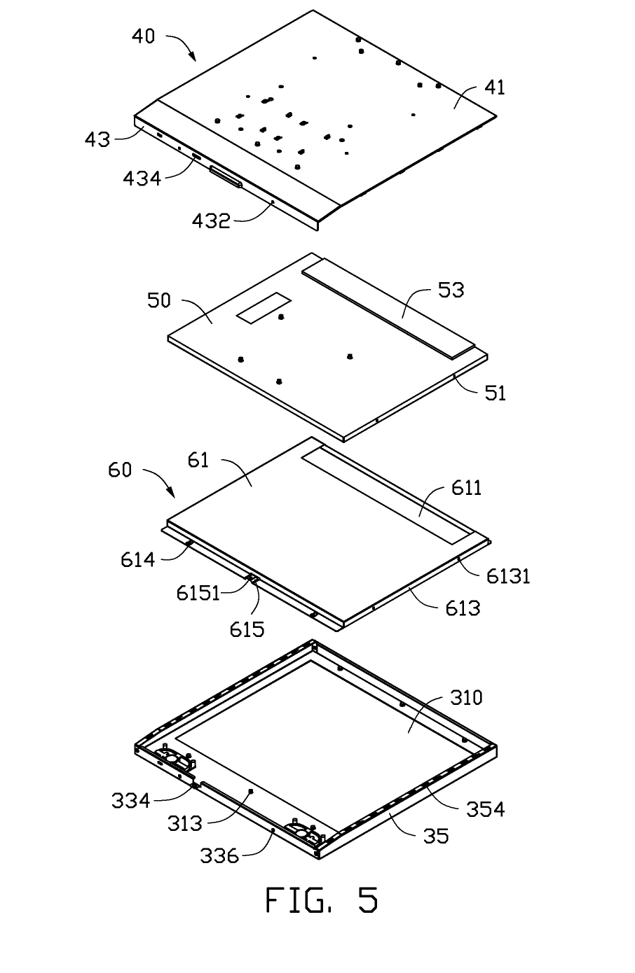

FIGS. 1 and 2 illustrate an embodiment of a mounting apparatus. The mounting apparatus comprises a panel cage 30, a cover 40 secured to the panel cage 30, a first securing member 20, and a second securing member 60 (shown in FIG. 5). The first securing member 20 is used to secure a first LCD 10, and the second securing member 60 is used to secure a second LCD 50. The first LCD 10 defines a plurality of first securing holes 13. The second LCD 50 defines a plurality of second securing holes 51, and a protruding portion 53 is located on the second LCD 50. In one embodiment, the first LCD 10 has a size less than the second LCD 50.

The panel cage 30 comprises a main panel 31, two first side panels 33 connected to opposite edges of the main panel 31, and two second side panels 35 connected to other opposite edges of the main panel 31. The main panel 31 defines an opening 310. In one embodiment, the opening 310 is substantially a rectangular. A plurality of positioning posts 312, and a mounting post 313 located between two of the plurality of positioning posts 312, are located on the main panel 31 and surrounds the opening 310. Two fixing holes 336 are defined in one of the two first side panels 33, and a clipping piece 334 extends from the one of the two first side panels 33. In one embodiment, the clipping piece 334 is substantially parallel to the first side panel 33. A plurality of clamping holes 354 are defined in each second side panel 35.

The cover 40 comprises a panel 41 and a clipping flange 43 substantially perpendicular to the panel 41. The clipping flange 43 defines two fastening holes 432 and a clipping hole 434. The two fastening holes 432 correspond to the two fixing holes 336. A plurality of clamping portions 45 are located on opposite sides of the panel 41.

The first securing member 20 comprises a first main body 21. The first main body 21 defines a first through hole 218. Two mounting panels 23 extend from opposite edges of the first through hole 218, and each mounting panel 23 defines two first mounting holes 230 corresponding to the securing holes 13. In one embodiment, each mounting panel 23 is substantially perpendicular to the first main body 21. A plurality of first cutouts 214 are defined in opposite edges of the first main body 21. A first mounting portion 210 is located on the first main body 21 and defines a first mounting hole 212 corresponding to the mounting post 313.

FIG. 5 illustrates that the second securing member 60 comprises a second main body 61. The second main body 61 defines a first through hole 611. The second main body 61 defines a receiving portion 613 used to receive the second LCD 50. Two second mounting holes 6131 are defined in opposite sides of the receiving portion 613 and correspond to the securing holes 13. A plurality of second cutouts 614 are defined in opposite edges of the second main body 61. A second mounting portion 615 is located on the second main body 61 and defines a second mounting hole 6151 corresponding to the mounting post 313.

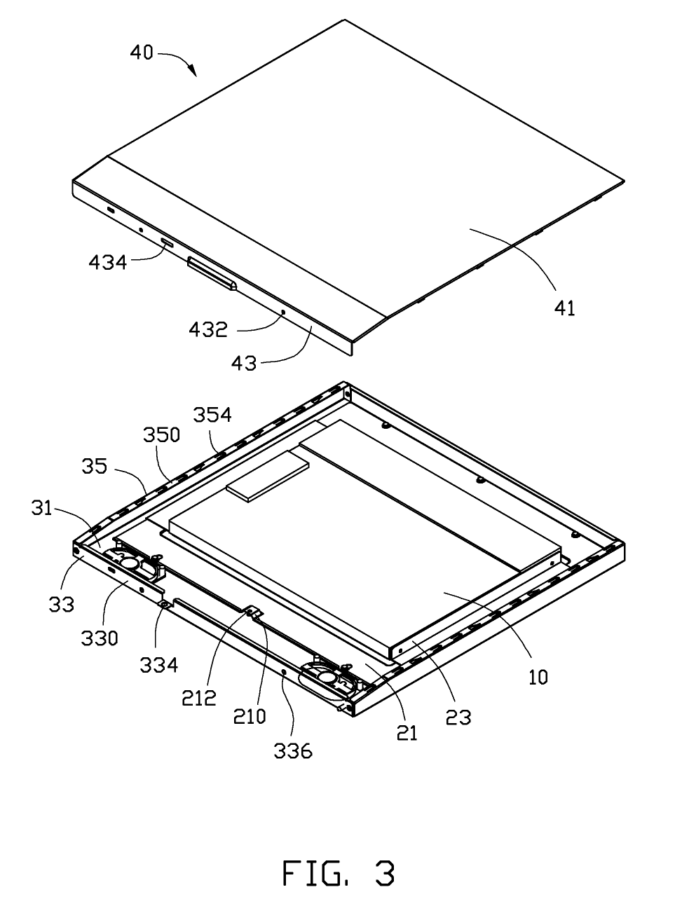

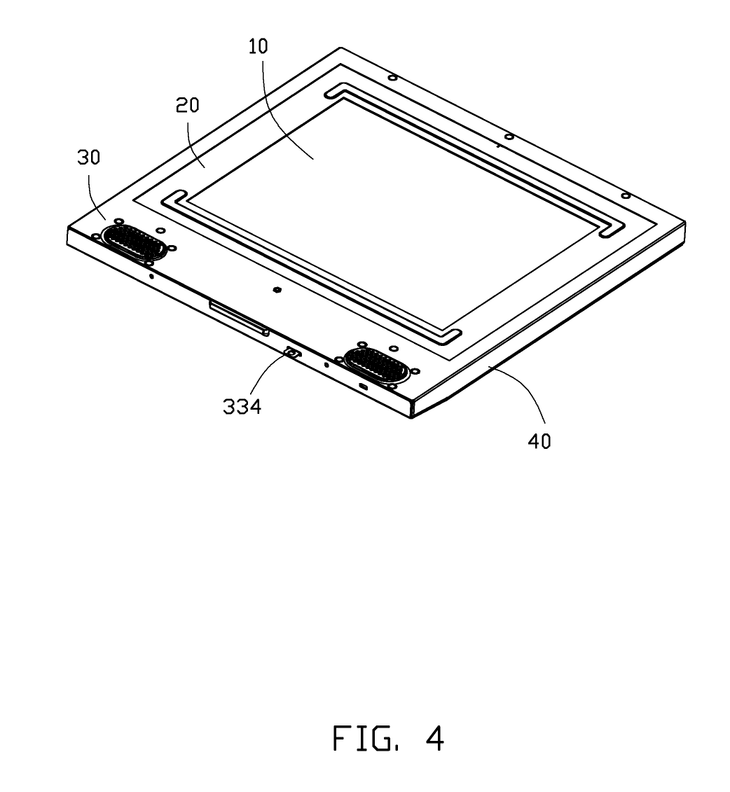

One of the first securing member 20 and the second securing member 60 can be alternatively secured to the panel cage 30. FIGS. 3-4 illustrate an embodiment of the first securing member 20 secured to the panel cage 30. In assembly, the first LDC 10 is located between the two mounting panels 230, and the first securing holes 13 are aligned with the first mounting holes 230. A plurality of first mounting members (not shown), such as screws, are engaged in the first securing holes 13 and the first mounting holes 230, so that the first LCD 10 is secured to the first securing member 20. The first securing member 20 is located on the main panel 31, and the plurality of cutouts 214 are aligned with the plurality of positioning posts 312. The first securing member 20 is slid to engage the plurality of positioning posts 312 in the plurality of cutouts 214, and the mounting post 313 is engaged in the first mounting hole 210. Thus, the first securing member 20 is secured to the panel cage 30.

The cover 40 is located on the panel cage 30. The clipping piece 330 is inserted into the clipping hole 434. The plurality of clamping portions 45 are clipped into the plurality of clamping holes 354, to secure the cover 40 to the panel cage 30. At this time, the first LCD 10 is located between the first securing member 20 and the cover 40.

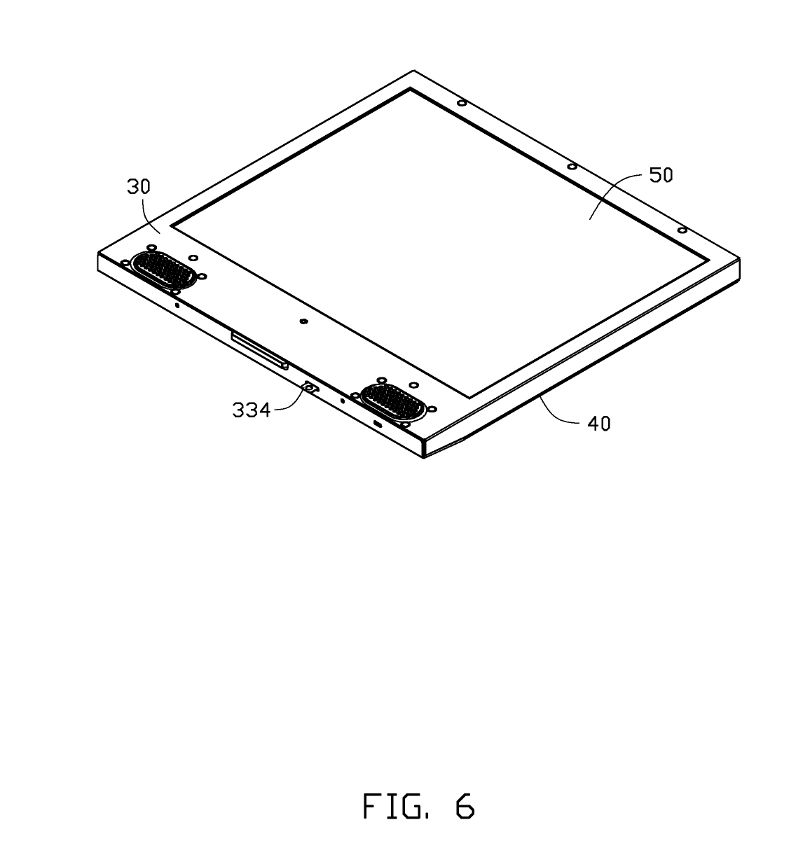

FIGS. 5-6 illustrates an embodiment of the second securing member 60 secured to the panel cage 30. In assembly, the second LCD 50 is received in the receiving portion 613, ad the second securing holes 51 are aligned with the second mounting holes 6131, a plurality of second mounting members (not shown), such as screws, are engaged in the second securing holes 51 and the second mounting holes 6131, so that the second LCD 50 is secured to the second securing member 60. The second securing member 60 is located on the main panel 31, and the plurality of second cutouts 614 are aligned with the plurality of positioning posts 312. The second securing member 60 is slid to engage the plurality of positioning posts 312 in the plurality of second cutouts 614, and the mounting post 313 is engaged in the second mounting hole 6151. Thus, the second securing member 60 is secured to the panel cage 30.

The cover 40 is located on the panel cage 30. The clipping piece 330 is inserted into the clipping hole 434. The plurality of clamping portions 45 are clipped into the plurality of clamping holes 354, to secure the cover 40 to the panel cage 30. At this time, the second LCD 50 is located between the second securing member 60 and panel cage 30.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting apparatus comprising:
a panel cage;
a first securing member configured to secure a first LCD;
a second securing member configured to secure a second LCD; and
a cover secured to the panel cage;
wherein one of the first securing member and the second securing member is secured to the panel cage; when the first securing member is secured to the panel cage, the first LCD is located between the first securing member and the cover; and when the second securing member is secured to the panel cage, the second LCD is located between the panel cage and the second securing member.

2. The mounting apparatus of claim 1, wherein the first securing member defines a plurality of first cutouts; and a plurality of positioning posts is located on the panel cage, to be slidably received in the plurality of first cutouts.

3. The mounting apparatus of claim 2, wherein each cutout is substantially U-shaped.

4. The mounting apparatus of claim 2, wherein the first securing member comprises a first mounting portion, the first mounting portion defines a first mounting hole, and a mounting post is located on the panel cage and is received in the first mounting hole.

5. The mounting apparatus of claim 4, wherein the panel cage comprises a main panel, the main panel defines an opening, and the mounting post and the plurality of positioning posts surround on the opening.

6. The mounting apparatus of claim 5, wherein the first securing member defines a first through hole configured for the first LCD towards the opening, and the second securing member defines a second through hole configured for a protruding portion of the second LCD extending through.

7. The mounting apparatus of claim 5, wherein the cover defines a clipping hole, the panel cage further comprises a first side panel that is substantially perpendicular to the main panel, and a clipping piece is located on the first side panel and clipped into the clipping hole.

8. The mounting apparatus of claim 7, wherein the panel cage further comprises a second side panel that is substantially perpendicular to the main panel and the first side panel; and the second side panel defines a plurality of clamping holes, and the cover comprises a plurality of clamping portions to engaged in the plurality of clamping holes.

9. The mounting apparatus of claim 1, wherein the first securing member comprises a first main body and two parallel mounting panels that is substantially perpendicular to the first main body; and the two parallel mounting panels are configured to secure the first LCD.

10. The mounting apparatus of claim 1, wherein the second securing member comprises a second main body, and the second main body defines a receiving portion that is configured to receive the second LCD.

11. A mounting apparatus comprising:
a panel cage comprising a main panel; a plurality of positioning posts and a mounting post located on the main panel;
a first securing member configured to secure a first LCD; the first securing member defines a plurality of first cutouts, and a first mounting portion is located on the first securing member;
a second securing member configured to secure a second LCD; the second securing member defines a plurality of second cutouts, and a second mounting portion is located on the first securing member; and
a cover secured to the panel cage;
wherein one of the first securing member and the second securing member is secured to the panel cage; when the first securing member is secured to the panel cage, the plurality of positioning posts is slidably received in the plurality of first cutouts, and the mounting post is engaged with the first mounting portion; and when the second securing member is secured to the panel cage, the plurality of positioning posts is slidably received in the plurality of second cutouts, and the mounting post is engaged with the second mounting portion.

12. The mounting apparatus of claim 11, wherein when the first securing member is secured to the panel cage, the first LCD is located between the first securing member and the cover; and when the second securing member is secured to the panel cage, the second LCD is located between the panel cage and the second securing member.

13. The mounting apparatus of claim 11, wherein each cutout is substantially U-shaped.

14. The mounting apparatus of claim 11, wherein the main panel defines an opening, and the mounting post and the plurality of positioning posts surround on the opening.

15. The mounting apparatus of claim 14, wherein the first securing member defines a first through hole configured for the first LCD towards the opening, and the second securing member defines a second through hole configured for a protruding portion of the second LCD extending through.

16. The mounting apparatus of claim 14, wherein the cover defines a clipping hole, the panel cage further comprises a first side panel that is substantially perpendicular to the main panel, and a clipping piece is located on the first side panel and clipped into the clipping hole.

17. The mounting apparatus of claim 16, wherein the panel cage further comprises a second side panel that is substantially perpendicular to the main panel and the first side panel; the second side panel defines a plurality of clamping holes, and the cover comprises a plurality of clamping portions to engaged in the plurality of clamping holes.

18. The mounting apparatus of claim 11, wherein the first securing member comprises a first main body and two parallel mounting panels that is substantially perpendicular to the first main body; and the two parallel mounting panels are configured to secure the first LCD.

19. The mounting apparatus of claim 11, wherein the second securing member comprises a second main body, and the second main body defines a receiving portion that is configured to receive the second LCD.
